(19) United States
(12) Patent Application Publication
(10) Pub. No.: US 2006/0088952 A1
(43) Pub. Date: Apr. 27, 2006

(54) Method and system for focused ion beam directed self-assembly of metal oxide island structures

(76) Inventors: James Frederick Groves, Charlottesville, VA (US); Yingge Du, Charlottesville, VA (US); Robert Wortman, Liberty Township, OH (US)

Correspondence Address: James F. Groves, 1354 Gristmill Dr., Charlottesville, VA, 22902, US

(21) Appl. No.: 11/039,305

(22) Filed: Jan. 21, 2005

Related U.S. Application Data
(60) Provisional application No. 60/538,096, filed on Jan. 21, 2004.
(60) Provisional application No. 60/578,158, filed on Jun. 9, 2004.

(51) Int. Cl. H01L 21/16; H01L 21/36

(52) U.S. Cl. 438/104; 438/479

(57) ABSTRACT

A process for guiding the growth of metal oxide islands of material which involves: presenting a metal oxide surface to a charged particle beam; impinging the metal oxide surface with ions from the charged particle beam; presenting said metal oxide surface to a deposition chamber; coating said surface with vapor to generate metal oxide islands.

### RELATED APPLICATIONS

The present invention claims priority from U.S. Provisional Application Ser. No. 60/538,096 filed on Jan. 21, 2004, entitled “Method and System for Focused Ion Beam Directed Self-Assembly of Metal Oxide Island Structures” the entire disclosure of which is hereby incorporated by reference herein.

The present invention claims priority from U.S. Provisional Application Ser. No. 60/578,158 filed on Jun. 9, 2004, entitled “Method and System for Focused Ion Beam Directed Self-Assembly of Metal Oxide Island Structures” the entire disclosure of which is hereby incorporated by reference herein.

### STATEMENT REGARDING FEDERALLY SPONSORED RESEARCH OR DEVELOPMENT

This invention was made with government support under the National Science Foundation Grant Nos. DMR-0080016 and EEC-0244436. The government has certain rights in the invention.

### REFERENCE TO SEQUENCE LISTING, A TABLE, OR A COMPUTER PROGRAM LISTING COMPAC DISC APPENDIX

Not Applicable

### BACKGROUND OF THE INVENTION

Numerous researchers are exploring techniques for nanoscale self-assembly of materials, seeking to create functional utility through engineered organization of materials at or just above the atomic scale. This invention pertains to a new, useful, and non-obvious method for defining the growth location of small islands or dots of one metal oxide material on the surface of a second metal oxide surface. This invention pertains to the field of materials science, more specifically nanotechnology, and most specifically guided (or directed) growth of material at the micro and nanoscale. The invention is focused upon a class of materials known as metal oxides.

### BRIEF SUMMARY OF THE INVENTION

This invention describes a new, useful, and nonobvious method to direct the self-assembly of metal oxide islands on metal oxide surfaces by using a focused ion beam (FIB) to modify the growth surface prior to thin film deposition. The link between FIB surface modification and metal oxide island growth has not been previously suggested or demonstrated. In this invention, ions (charged atoms) are implanted into a metal oxide surface, modifying a specific location on the surface prior to metal oxide thin film growth. As the result of the implant, micro and/or nanostructured island growth occurs in a location controlled by the implant. This ability has not been previously demonstrated. This new ability to specify metal oxide island growth location could enable numerous new engineered devices for a myriad of useful applications based upon the known (and unknown) properties of metal oxides. Known, potentially important characteristics of various metal oxides include, but are not limited to, high temperature superconductivity, ferroelectricity, ferrielectricity, ferromagnetism, ferrimagnetism, colossal magnetoresistance, non-linear optical properties, catalytic behavior, and chemical stability in open air and many liquid environments. When compared with conventional semiconductors, metal oxide materials are more stable in the natural, open air the environment.

### BRIEF DESCRIPTION OF THE SEVERAL VIEWS OF THE DRAWING

The objects, features, and advantages of the present invention, as well as the invention itself, will be more fully understood from the following detailed description of the invention, when read together with the accompanying drawings:

FIG. 1: a) SrTiO₃ (100) at end of FIB patterning, etching, and annealing b) at the end of Cu₂O deposition. (˜3000 Ga⁺ ions/spot, 1000° C./30 min. anneal, 700° C. Cu₂O growth, 1×10⁻⁵ Torr oxygen pressure).

FIG. 2: (a) Atomic force microscope (AFM) image showing the preferential growth of Cu₂O nanodots on the edges of the FIB implant zones, (b) a higher resolution scan of one FIB implant zone with Cu₂O nanodot growth. The light regions are Cu₂O nanodots.

FIG. 3: Atomic force microscope (AFM) image and line scan of (a) a substrate region following focused ion beam modification. Dark regions are the focused ion beam (FIB) modified zones. Ion density was 5.57×10¹⁸ ions/cm² with 4.4×10⁸ Ga⁺ ions/ spot (70 pA beam current and 1 s dwell time), (b) the same modified region after substrate etching and annealing, (c) the same region after subsequent cleaning and nanodot synthesis. The light regions are Cu₂O nanodots.

### DETAILED DESCRIPTION OF THE INVENTION

It is known in the literature that, during thin film growth of one material (e.g. element or compound) on another, the depositing material can distribute itself across the surface in one of three modes—1) as a continuous, uniform layer (Frank—van der Merwe growth), 2) as a continuous, nonuniform layer with islands growing above the initial continuous layer (Stranski-Krastanov growth), and 3) as a discontinuous distribution of islands (Volmer—Weber growth). Whether a depositing material organizes itself via growth mode one, two, or three depends upon a subtle interplay of surface energy, interface energy, and lattice mismatch strain energy. When depositing materials assemble by growth mode two or three, the lateral position of island formation across the surface is largely random if nature is left to do the job alone. However, recent work in the literature has begun to demonstrate that the location of island formation in semiconductors can be selected by creating mesa structures (e.g. steps) on the deposition surface prior to thin film deposition [1], by depositing the thin film material through masks [2], and by using a focused ion beam to modify the surface prior to thin film growth [3].

While all of these techniques have been reported to enable guided or directed island growth in semiconductors, they have not been previously shown to enable such growth in metal oxides. Indeed, in the case of focused ion beam (FIB) guided growth, it seems reasonable, based on the literature, to believe that the guided growth technique is not immediately transferable to metal oxides. The FIB semiconductor guided growth literature [3] suggests that the technique is most likely able to specify island growth location because the element used in the focused ion beam, gallium, is known to act as a surfactant in the germanium-silicon material system where FIB guided growth has been reported. The literature suggests that, following implant, the gallium returns to the substrate surface during subsequent heat treatment where it can act as a surfactant. The literature states that it is gallium's behavior as a surfactant that motivates island growth in specific locations. There are no known reports to show that gallium returns to the surface of a metal oxide during a heat treatment imposed after implant. Furthermore, there are no known reports in the literature of gallium acting as a surfactant in a metal oxide material. The literature also suggests [3] that point defects induced by the FIB implant could contribute to directed growth in semiconductors. There is no published information that suggests that point defects would control the growth location of metal oxide islands. Finally the literature [3] also suggests that guided growth in semiconductors could occur as the result of FIB implant induced strain fields. The literature does not provide evidence to support this claim, and there is no published information that suggests that strain would control the growth location of metal oxide islands. Therefore, based on the explanations provided in the literature which suggest how to use a focused ion beam to guide island growth in semiconductor systems, it is non-obvious that it should be possible to use a focused ion beam of gallium (or any other element) to guide or direct the growth of metal oxide islands.

While the literature [3] also suggests that topography and deposition temperature could play a role in determining semiconductor island growth location, it does not provide reason to believe that FIB techniques for semiconductor patterning are transferable to metal oxides. Indeed, researchers who study semiconductor, metal, or metal oxide materials will generally agree that surface characteristics and thin film growth behavior in these systems is significantly different [4], “At a more fundamental level, there are a number of scientific challenges associated with oxide surfaces that are relatively unexplored. These include understanding the nature of oxide surface structures, surface electronic properties, the forces governing oxide surface reactivity, and the mechanical properties of oxide surfaces. It is no understatement that despite its technological importance, oxide surface science is in its infancy compared to that of metals or semiconductors.” Thus, the fact that an FIB technique works to guide semiconductor island growth would not suggest to anyone skilled in the art that the technique is transferable to metal oxides. Such an extension is simply not obvious.

Metal oxides have many valuable properties [4, 5], and the ability to deposit metal oxide islands in specific locations on metal oxide surfaces should be useful. Known, potentially important characteristics of various metal oxides include, but are not limited to, high temperature superconductivity, ferrielectricity, ferroelectricity, ferromagnetism, ferrimagnetism, colossal magnetoresistance, non-linear optical properties, and chemical stability in open air and many liquid environments. Researchers have recognized the value of creating micro and nanoscale metal oxide structures. Indeed, the use of very thin continuous metal oxide films is a core aspect of the microelectronic industry where CMOS (complementary metal-oxide-semiconductor) technology is the foundation of modern electronic systems (e.g. computers and cell phones). Other researchers have recognized that FIBs can be used to define the lateral dimensions of continuous metal oxide films for device structures [6, 7]. In contrast, the use of metal oxides in the form of small, discontinuous islands formed via Stranski-Krastanov or Volmer-Weber growth modes is relatively unexplored. Thus the techniques described in detail here hold the potential to open new, useful applications of metal oxides by employing a non-obvious guiding technique.

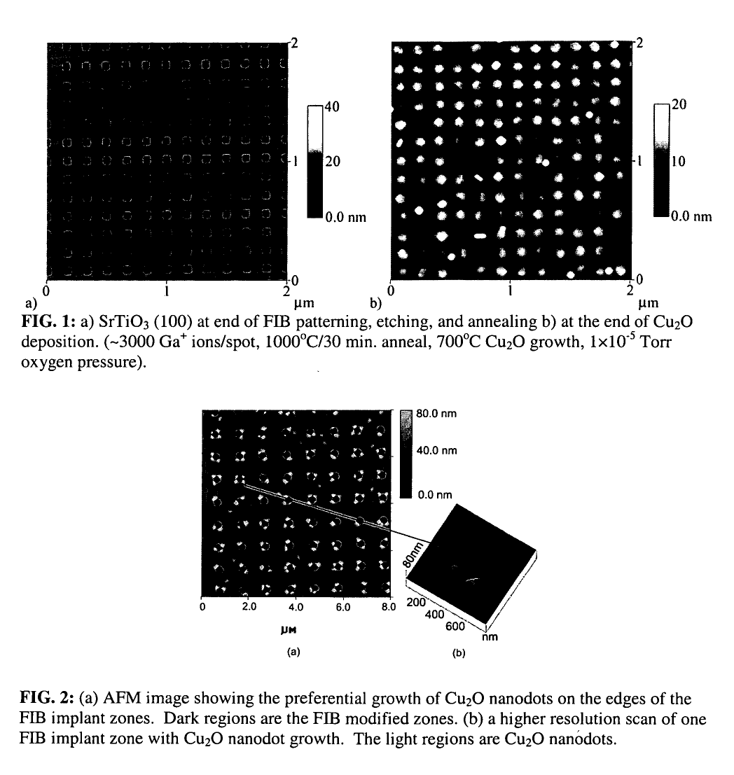

Focused ion beams are readily available, highly flexible tools for surface modification. It is currently possible to purchase focused ion beam columns or tools from commercial companies. These tools are most often used for microelectronic device inspection and repair. These devices make it possible to create a focused beam of charged particles (i.e. ions) that can be accelerated and directed at a surface. Various ion beam parameters can be changed, including the elemental composition of the beam, the voltage used to accelerate the beam, and the focus of the beam (i.e. spot size). This beam can then be directed at a surface where the impact of the individual ions modifies the surface. Changes to each one of these parameters (beam composition, accelerating voltage, angle of ion impact, and focus), individually or in concert, can vary the surface modification imposed by the beam. When the beam is directed at the surface it can remain focused at a particular location for varying lengths of time, implanting one to many millions of atoms in each location. When the FIB is directed towards a surface, it can dwell on individual spots on the surface, or it can be moved across the surface to form surface modified regions or intricate patterns. Each mode can be useful for motivating metal oxide island growth in specific locations. For relatively low implant dosage, a FIB modified spot could motivate the directed, site-specific growth of an individual metal oxide island (FIG. 1). In other cases, an FIB modified spot, region, or pattern could motivate the directed, site-specific growth of a set of metal oxide islands (FIG. 2).

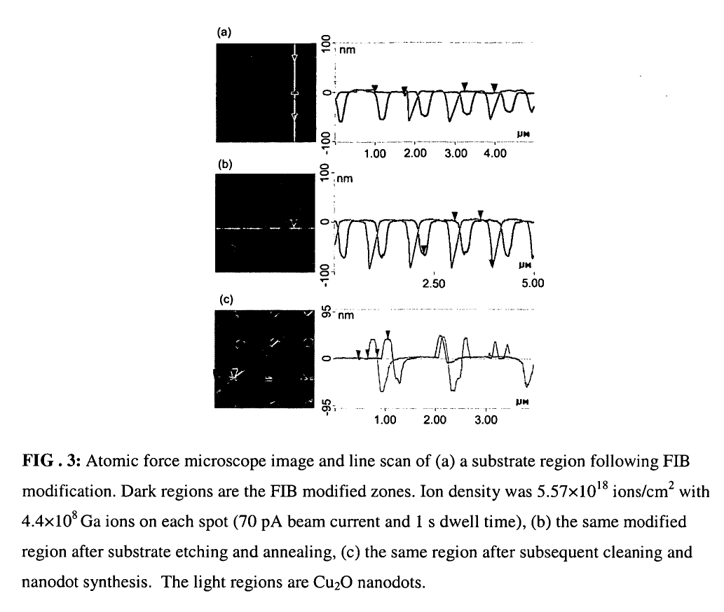

To make use of this invention, one might follow a preferred procedure such as the following (FIG. 3). First, identify the metal oxide material system of interest in which deposition of one metal oxide on a separate metal oxide leads to film growth by either the Stranski-Krastanov or the Volmer-Weber growth mode. Second, clean, pattern, and prepare the selected substrate surface. Surface patterning should involve focusing the ion beam at one or more spots on the metal oxide surface. It could also involve drawing an intricate pattern across the metal oxide surface with the FIB. Third, deposit the selected metal oxide material under conditions known to generate island deposits, via either the Stranski-Krastanov or Volmer-Weber growth mode.

The utility of this invention can be demonstrated by considering a specific example of material system and application to which the process could be applied. Consider the deposition of Cu₂O islands on a SrTiO₃ substrate [8]. The photocatalytic decomposition of water on Cu₂O and SrTiO₃ under visible light irradiation has been reported [8, 9]. A recent report indicates that Cu₂O can act as a stable mechanocatalyst in water [10] while a second report suggests that Cu₂O can be a stable component in an electrochemical photovoltaic cell [11]. These reports raise the prospect of forming a stable catalytic platform (Cu₂O on SrTiO₃) that serves as the basis of a hydrogen production system, useful in fuel cells, or a bioremediation system, for breakdown of unwanted organics. Arrangement of a high density of Cu₂O islands on SrTiO₃ substrates could enhance the efficiency of mechanochemical activity. The invention described here represents one means for generating a high density array of Cu₂O islands on SrTiO₃.

In the specific process of material preparation for the application described above, the FIB implantation is the key factor and is the subject of this invention. In addition to the basic process described above, the process could also include surface cleaning and preparation routines that are available in the literature [8, 12, 13]. In the figures shown here, (FIG. 1, FIG. 2, and FIG. 3), the ion beam was focused to a small diameter (on order 30 nm) and sent towards the SrTiO₃ substrate with an accelerating voltage of 30 keV. In each location where it is desirable to grow a Cu₂O island deposit, the FIB could modify the SrTiO₃ surface with gallium ions, with the quantity of gallium ions ranging from tens or hundreds to millions or billions. This surface modification would then motivate Cu₂O island growth directly on top of the SrTiO₃ region modified by the FIB or on the edges of the modified spots.

In addition to the reduction to practice work already completed on the Cu₂O—SrTiO₃ material system, additional study of the literature and knowledge of crystallography has allowed us to identify other promising material systems whose growth can likely be controlled by these same techniques. Those skilled in the art will immediately realize that other metal oxide deposits assembling on metal oxide surfaces by the Stranski-Krastanov or Volmer-Weber growth mode can have their growth processes guided by the techniques disclosed here. Additional material systems like CoCr₂O₄ or CoFe₂O₄ [14] as the nanodot material on a MgAl₂O₄ substrate should lend themselves to this process. The CoFe₂O₄ and MgAl₂O₄ have the same cubic spinel crystal structure with the CoFe₂O₄ having a lattice approximately 4% larger than the MgAl₂O₄. These parameters should motivate nanodot growth, and we believe that the FIB directed self-assembly techniques disclosed here should prove useful in directing the growth of this magnetic system.

To be useful for data storage applications, the material of choice must be a hard magnet; that is, it must be able to hold a magnetic moment (in order to be used for data storage). Of the different types of magnetic materials out there, the metal oxides have the best properties for our purposes. Thus, the guided growth process described here has great utility. Consider that metal oxides are chemically stable, which is very important when dealing with such small magnetic structures. Interestingly, pure magnetic metals at this size would oxidize quickly, and in most cases lose their magnetic properties. Also, hard magnets that are ceramics have been used for transformer cores and similar applications for years. To be considered in magnetic storage applications, the coercivity of the material must be 40 kA/m or greater [15]. The CoFe₂O₄—MgAl₂O₄ system appears to satisfy this additional requirement. CoCr₂O₄ also appears promising.

### REFERENCES

1. T. I. Kamins and R. S. Williams, Appl. Phys. Lett. 71, 1201 (1997).
2. M. Ichikawa, J. Phys.: Condens. Matter 11, 9861 (1999).
3. M. Kammier, R. Hull, M. C. Reuter, and F. M. Ross, Appl. Phys. Lett. 82, 1093 (2003).
4. S. A. Chambers, Surface Science Reports, 39, 105 (2000).
5. S. Ikeda, T. Takata, T. Kondo, G. Hitoki, M. Hara, J. N. Kondo, K. Domen, H. Hosono, H. Kawazoe, and A. Tanaka, Chem. Commun. 2185 (1998).
6. T. Ishibashi, T. Kawahara, H. Kaneko, and K. Sato, IEEE Trans. On Appl. Superconductivity, 9(2), 2383 (1999).
7. K. Yonemitsu, K. Inagaki, T. Ishibashi, S. Kim, K. Lee, and K. Sato, Physica C, 367, 414 (2002).
8. I. Lyubinetsky, S. Thevuthasan, D. E. McCready, and D. R. Baer, J. Appl. Phys., in press (2003).
9. H. Kato and A. Kudo, J. Phys. Chem. B, 106, 5029 (2002).
10. M. Hara, T. Kondo, M. Komoda, S. Ikeda, K. Shinohara, A. Tanaka, J. N. Kondo, and K. Domen, Chem. Commun. 357 (1998).
11. P. E. de Jongh, D. Vanmaekelbergh, and J. J. Kelly, Chem. Commun. 1069 (1999).
12. G. Koster, B. L. Kropman, G. J. H. M. Rijnders, D. H. A. Blank, and H. Rogalla, Appl. Phys. Lett. 73, 2920 (1998).
13. S. Gan, Y. Liang, and D. R. Baer, Surf. Sci., 459, L498 (2000).
14. N. Spaldin, Magnetic Materials: Fundamentals and Device Applications, (Cambridge University Press: New York, ISBN 0 521 01658 4) (2003).
15. C. A. Ross, “Patterned Magnetic Recording Media,” Annu. Rev. Mater. Res., 31, pp. 203-35 (2001).

We claim:

1. A process for guiding the growth of metal oxide islands of material comprising:
presenting a metal oxide surface to a charged particle beam;
impinging the metal oxide surface with ions from the charged particle beam;
presenting said metal oxide surface to a deposition chamber;
coating said surface with vapor to generate metal oxide islands.

2. The process for guiding the growth of metal oxide islands as claimed in claim 1, wherein said metal oxide surface is a single crystal.

3. The process for guiding the growth of metal oxide islands as claimed in claim 1, wherein said metal oxide surface has a form selected from the group consisting of flat surfaces, multifaceted surfaces, and curved surfaces.

4. The process for guiding the growth of metal oxide islands as claimed in claim 1, wherein said charged particle beam is a material selected from the group consisting of elemental materials and mixtures thereof.

5. The process for guiding the growth of metal oxide islands as claimed in claim 1, wherein said charged particle beam employs a mass selecting filter for extraction of a specific elemental material for impingement upon said metal oxide surface.

6. The process for guiding the growth of metal oxide islands as claimed in claim 1, wherein said charged particle beam is focused by an electromagnet.

7. The process for guiding the growth of metal oxide islands as claimed in claim 1, wherein said charged particle beam is contained within said deposition chamber.

8. The process for guiding the growth of metal oxide islands as claimed in claim 1, wherein said charged particle beam impinges said metal oxide surface with particles possessing a kinetic energy of from 10 electron volts up to, but not including, 50 kiloelectron volts.

9. The process for guiding the growth of metal oxide islands as claimed in claim 1, wherein said charged particle beam impinges said metal oxide surface with charged particles possessing a kinetic energy of from 50 kiloelectron volts up to 1 million electron volts.

10. The process for guiding the growth of metal oxide islands as claimed in claim 1, wherein said charged particle beam is applied to said metal oxide surface at a position on said metal oxide surface which is varied by an electromagnetic rastering means.

11. The process for guiding the growth of metal oxide islands as claimed in claim 10, wherein said charged particle beam impinges one or more ions upon each metal oxide surface position selected by said electromagnetic rastering means.

12. The process for guiding the growth of metal oxide islands as claimed in claim 1, wherein said charged particle beam is negatively charged.

13. The process for guiding the growth of metal oxide islands as claimed in claim 1, wherein said charged particle beam is positively charged.

14. The process for guiding the growth of metal oxide islands as claimed in claim 1, wherein said vapor is a mixture of metal elements and oxygen.

15. The process for guiding the growth of metal oxide islands as claimed in claim 1, in which the kinetic energy of said charged particle beam is varied as electromagnetic rastering means move the beam to different positions on said metal oxide surface.

16. The process for guiding the growth of metal oxide islands as claimed in claim 1, in which a mass selecting filter applied to said charged particle beam is varied as electromagnetic rastering means move the beam to different positions on said metal oxide surface.

17. The process for guiding the growth of metal oxide islands as claimed in claim 1, wherein said charged particle beam impinges upon said metal oxide surface at a 90° angle.

18. The process for guiding the growth of metal oxide islands as claimed in claim 1, wherein said charged particle beam impinges upon said metal oxide surface at an angle less than 90°.

19. The process for guiding the growth of metal oxide islands as claimed in claim 1, wherein said vapor consists of elemental materials that will form lattice mismatched metal oxide islands on said metal oxide substrate.

20. The process for guiding the growth of metal oxide islands as claimed in claim 1, wherein said substrate is SrTiO₃, Al₂O₃, MgO, ZnO, TiO₂, or MgAl₂O₄.

21. The process for guiding the growth of metal oxide islands as claimed in claim 1, wherein said vapor forms Cu₂O, NiO, CoCr₂O₄, Fe₂O₃, ZnO, or CoFe₂O₄.
